(19) United States
(12) Patent Application Publication
(10) Pub. No.: US 2017/0062520 A1
(43) Pub. Date: Mar. 2, 2017

(54) MAGNETORESISTIVE MEMORY DEVICE AND MANUFACTURING METHOD OF THE SAME

(71) Applicant: KABUSHIKI KAISHA TOSHIBA, Tokyo (JP)

(72) Inventor: Motoyuki SATO, Seoul (KR)

(73) Assignee: KABUSHIKI KAISHA TOSHIBA, Tokyo (JP)

(21) Appl. No.: 15/061,887

(22) Filed: Mar. 4, 2016

Related U.S. Application Data
(60) Provisional application No. 62/212,972, filed on Sep. 1, 2015.

(51) Int. Cl. H01L 27/22; H01L 43/08; H01L 43/12; H01L 43/02

(52) U.S. Cl. CPC H01L 27/226; H01L 43/02; H01L 43/08; H01L 43/12

(57) ABSTRACT

According to one embodiment, a magnetoresistive memory device includes a magnetoresistive element includes a first magnetic layer, a second magnetic layer, and a nonmagnetic layer between the first magnetic layer and the second magnetic layer, and a sidewall insulating film provided on a sidewall of the magnetoresistive element. The sidewall insulating film includes a first insulating film in contact with a sidewall of the second magnetic layer, a second insulating film in contact with a sidewall of the nonmagnetic layer, and a third insulating film in contact with a sidewall of the first magnetic layer. A composition of the second insulating film is different from a composition of the first and third insulating film.

### CROSS-REFERENCE TO RELATED APPLICATIONS

This application claims the benefit of U.S. Provisional Application No. 62/212,972, filed Sep. 1, 2015, the entire contents of which are incorporated herein by reference.

### FIELD

Embodiments described herein relate generally to a magnetoresistive memory device and a method of manufacturing the same.

### BACKGROUND

In recent years, a large-capacity magnetoresistive random access memory (MRAM) using a magnetic tunnel junction (MTJ) element has attracted expectation and attention. In the MTJ element, one of the two magnetic layers holding a tunnel barrier layer therebetween is used as a fixed-magnetization layer (reference layer) wherein the direction of magnetization is fixed, and the other is used as a variable-magnetization layer (storage layer) wherein the direction of magnetization is easily reversible.

Further, in the MRAM, an insulating film, such as a silicon nitride film (SiN), is provided on the sidewall of the MTJ element in order to enhance the reliability of the element.

### BRIEF DESCRIPTION OF THE DRAWING

FIG. 1 is a cross-sectional view showing the element structure of a magnetoresistive memory device according to a first embodiment.

FIG. 2 is an enlarged cross-sectional view of a portion marked by the broken line in FIG. 1.

FIGS. 3A to 3G are cross-sectional views showing a process of manufacturing the magnetoresistive memory device of the first embodiment.

FIG. 4 is a cross-sectional view showing the element structure of a magnetoresistive memory device according to a second embodiment.

FIG. 5 is an enlarged cross-sectional view of a portion marked by the broken line in FIG. 4.

FIGS. 6A to 6C are cross-sectional views showing a process of manufacturing the magnetoresistive memory device of the second embodiment.

FIG. 7 is a circuit diagram showing the memory cell array of an MRAM according to a third embodiment.

FIG. 8 is a cross-sectional view showing the structure of a memory cell portion of the MRAM shown in FIG. 7.

### DETAILED DESCRIPTION

In general, according to one embodiment, a magnetoresistive memory device comprising: a magnetoresistive element includes a first magnetic layer, a second magnetic layer, and a nonmagnetic layer between the first magnetic layer and the second magnetic layer; and a sidewall insulating film provided on a sidewall of the magnetoresistive element, and including a first insulating film in contact with a sidewall of the second magnetic layer, a second insulating film in contact with a sidewall of the nonmagnetic layer, and a third insulating film in contact with a sidewall of the first magnetic layer, wherein a composition of the second insulating film is different from a composition of the first and third insulating film.

Referring now to the accompanying drawings, magnetoresistive memory devices according to the embodiments will be described.

### First Embodiment

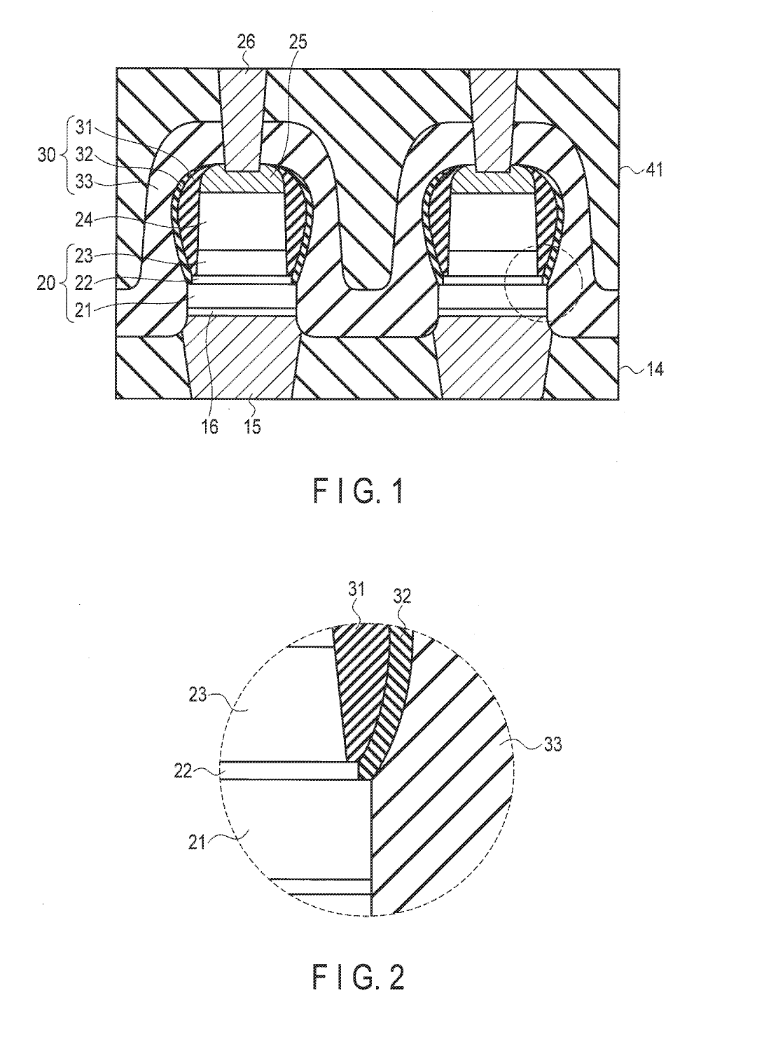

FIG. 1 is a cross-sectional view showing the element structure of a magnetoresistive memory device according to a first embodiment.

An interlayer insulating film 14, such as a silicon oxide film, is formed on a silicon substrate (not shown), and a lower electrode 15 is embedded in the interlayer insulating film 14. A buffer layer 16 is formed on the lower electrode 15. The buffer 16 is used to enhance the crystallinity of a layer formed thereon.

It is sufficient if the material of the lower electrode 15 enables the electrode to be reliably buried in a contact hole, and exhibits sufficient conductivity. As this material, Ta, W, TiN, TaN or Cu can be used.

Furthermore, for the buffer layer 16, a material containing Al, Be, Mg, Ca, Sr, Ba, Sc, Y, La, Si, Zr, Hf, W, Cr, Mo, Nb, Ti, Ta, V or the like can be used. Moreover, the buffer layer may also include a boride of any of these. The boride is not limited to a binary compound consisting of two kinds of elements but it may be also a ternary compound consisting of three kinds of elements. In other words, the material may be a mixture of binary compounds.

For example, HfB, MgAlB, HfAlB, ScAlB, ScHfB, HfMgB may be used. Furthermore, the above-described material may be stacked.

With use of a metal having a high melting point and a boride thereof, the diffusion of the material of the buffer layer to the magnetic layer can be suppressed, thereby making it possible to prevent the deterioration of the MR ratio. Here, metals having a high melting point are those having a melting point higher than those of Fe and Co, which are, for example, Zr, Hf, W, Cr, Mo, Nb, Ti, Ta, and V.

On the buffer layer 16, an MTJ element 20, which is formed by stacking the storage layer (first magnetic layer) 21, a tunnel barrier layer (nonmagnetic layer) 22, and a reference layer (second magnetic layer) 23, is provided. The storage layer 21 has magnetic anisotropy perpendicular to its surface, has its direction of magnetization set variable, and is formed of, for example, CoFeB. The tunnel barrier layer 22 is used to cause a tunnel current to flow therethrough, and is formed of, for example, MgO. Furthermore, the reference layer 23 has magnetic anisotropy perpendicular to its film surface, and has its direction of magnetization fixed. This layer is formed of, for example, CoFeB.

The material of the magnetic layers of the storage layer 21 and the reference layer 23 is not limited to CoFeB. It is sufficient if it contains Co and Fe. Moreover, the material is not limited to containing Co and Fe, but may be other ferromagnetic materials. In addition, the material of the tunnel barrier layer is not limited to MgO, but this tunnel barrier layer may be an Al oxide film (Al₂O₃). Moreover, it is also possible to use the ferromagnetic materials such as CoPt, CoNi, and CoPd as the reference layer 23.

On the reference layer 23 of the MTJ element 20, a shift adjustment layer (third magnetic layer) 24 is formed. The shift adjustment layer 24 is used to remove or reduce stray magnetic field from the reference layer 23, and is opposite in direction of magnetization to the reference layer 22. As the material of the shift adjustment layer 24, CoPt, CoNi, or CoPd can be used.

A conductive cap layer (mask material layer) 25 is formed on the shift adjustment layer 24. A contact plug (upper electrode) 26 is formed on the cap layer 25. The upper electrode 26 is connected to an interconnect, such as a bit line (not shown).

The cap layer 25 may be formed of a conductive material, such as Pt, W, Ta, Ru, etc. The contact plug 26 may be formed of Ta, W, Ti, TaN or TiN. Further, the cap layer 25 is not limited to a layer of a conductive material, but may be formed of an insulating film of, for example, SiN. Furthermore, the cap layer 25 may be formed of a laminated structure of a conductive layer and an insulating layer.

A sidewall insulating film 30 is formed to cover the sidewall of the MTJ element 20. The sidewall insulating film 30 has a three-layer structure of SiN/SiO₂/SiN. A silicon nitride film (first insulating film) 31 as a first sidewall insulating film is formed to cover the side surfaces of the reference layer 23, the shift adjustment layer 24 and the cap layer 25. A silicon oxide (second insulating film) 32 as a second sidewall insulating film is formed to cover the sidewall of the tunnel barrier layer 22 and the silicon nitride film 31. A silicon nitride film (third insulating film) 33 as a third sidewall insulating film is formed to cover the sidewall of the storage layer 21 and the silicon oxide film 32.

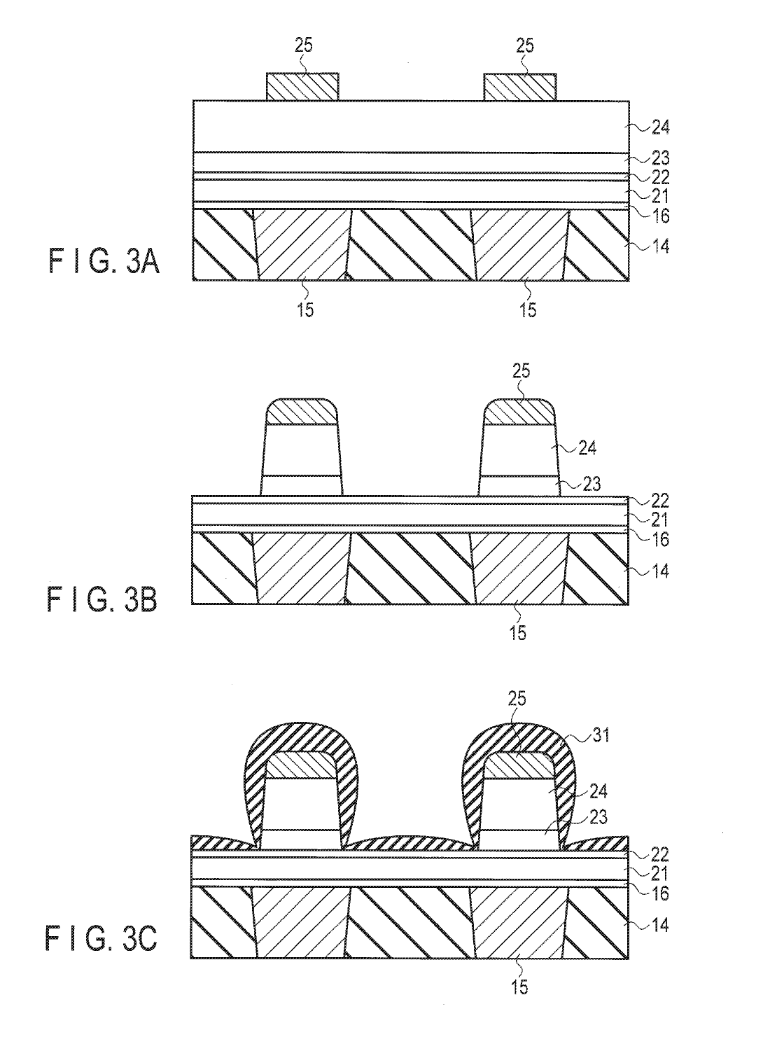

As is shown in the enlarged view of FIG. 2 indicating the portion of FIG. 1 marked by the broken line, the storage layer 21 is formed slightly wider than the tunnel barrier layer 22. Thus, the end of the storage layer 21 is not level with the end of the tunnel barrier layer 22, whereby the storage layer 21 has an outwardly protruding step. Further, the tunnel barrier layer 22 is formed slightly wider than the reference layer 23. Thus, the end of the tunnel barrier layer 22 is not level with the end of the reference layer 23, whereby the tunnel barrier layer 22 has an outwardly protruding step.

Those steps enable the sidewall insulating film 30 to be formed such that only the silicon nitride film 31 is in contact with the side surface of the reference layer 23, only the silicon oxide film 32 is in contact with the side surface of the tunnel barrier layer 22, and only the silicon nitride film 33 is in contact with the side surface of the storage layer 21. Although the bottom of the silicon nitride film 31 is in contact with the upper surface of the end portion of the tunnel barrier layer 22, the area of this portion is very small. Similarly, although the bottom of the silicon oxide film 32 is in contact with the upper surface of the end portion of the storage layer 21, the area of this portion is also very small.

In addition, an interlayer insulating film 41 formed of, for example, a silicon oxide film is provided on a structure comprising the MTJ element 20, the shift adjustment layer 24, the cap layer 25, the sidewall insulating film 30, etc. The contact plug 26 extends to the cap layer 25 through the interlayer insulating film 41 and the silicon nitride film 33.

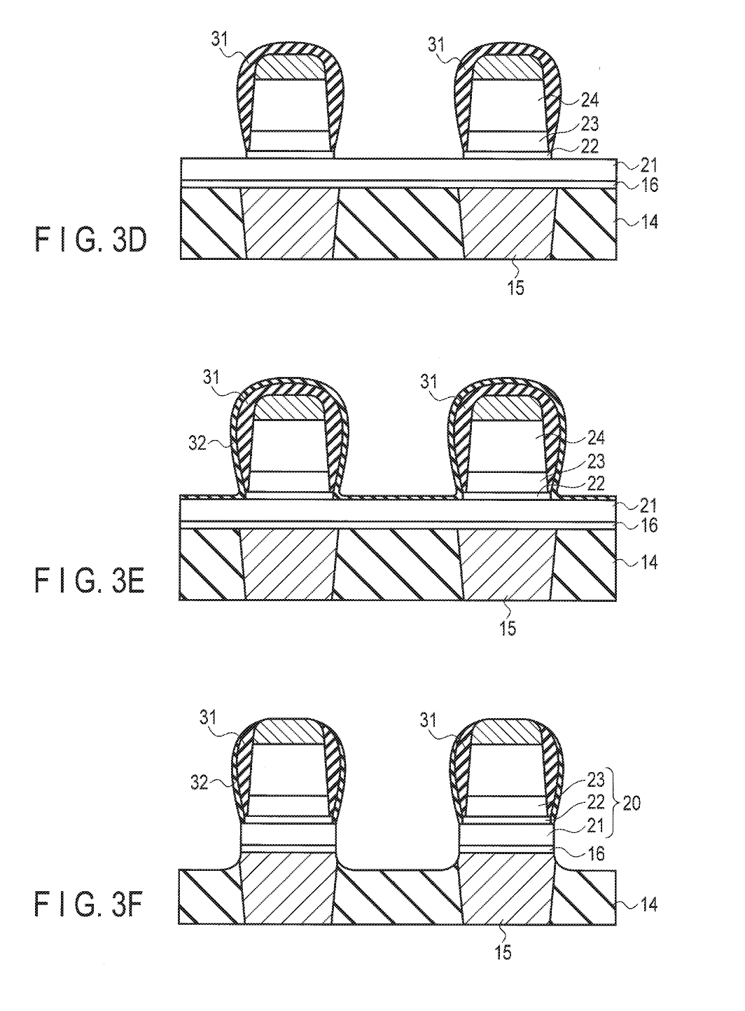

Referring then to FIGS. 3A to 3G, a description will be given of a process of manufacturing the magnetoresistive memory device of the embodiment.

First, as shown in FIG. 3A, the buffer layer 16 formed of Hf or AlN, the storage layer 21 formed of, for example, CoFeB, the tunnel barrier layer 22 formed of, for example, MgO, the reference layer 23 CoFeB, and the shift adjustment layer 24 comprising, for example, Co and Pt, are formed on a foundation substrate comprising the interlayer insulating film 14 with the lower electrode 15 buried therein. After forming, on the shift adjustment layer 24, the cap layer (mask material layer) 25 formed of, for example, W, the cap layer 25 is processed in accordance with the pattern of the MTJ element.

Subsequently, as shown in FIG. 3B, the shift adjustment layer 24 and the reference layer 23 are etched by ion beam etching (IBE), using the cap layer 25 as a mask. At this time, by detecting Mg by secondary ion mass spectroscopy (SIMS), etching can be stopped as soon as possible when the etching has reached the MgO tunnel barrier layer 22. Instead of IBE, reactive ion etching (RIE) can be used.

Subsequently, as shown in FIG. 3C, the silicon nitride film (first insulating layer) 31 whose nitrogen concentration is higher than its stoichiometric mixture ratio is formed as a first sidewall insulating film by plasma CVD. Since the nitrogen concentration is higher than the stoichiometric mixture ratio, the silicon nitride film 31 exhibits degraded step coverage as shown in the figure. That is, the silicon nitride film 31 is extremely thin near the bottom of the reference layer 23.

Subsequently, as shown in FIG. 3D, part of the silicon nitride film 31 and the tunnel barrier layer 22 are etched by RIE. At this time, the storage layer 21 below is used as an etching stopper. In this etching, select ratios between SiN and MgO and between W and CoFeB can be sufficiently secured, if a CF-based gas is used. Further, since the tunnel barrier layer 22 is subjected to selective etching using the sidewall silicon nitride film 31 and the cap layer 25 as masks, the above-mentioned steps shown in FIG. 2 are formed.

Subsequently, as shown in FIG. 3E, the silicon oxide film (second insulating film) 32 as a second sidewall insulating film is formed in a low-temperature (300° C. or less) atomic-layer-deposition process. That is, the silicon oxide film 32 is formed to cover the sidewall of the tunnel barrier layer 22 and the silicon nitride film 31. The silicon oxide film 32 is formed to have substantially the same thickness as the tunnel barrier layer 22.

Subsequently, as shown in FIG. 3F, part of the silicon oxide film 32 and the storage layer 21 are etched by IBE. That is, part of the silicon oxide film 32 placed on the storage layer 21 is etched, and the storage layer 21 is etched using the remaining silicon oxide film 32 and the cap layer 25 as masks. At this time, since the storage layer 21 is selectively etched using the sidewall silicon oxide film 32 as a mask, the above-mentioned steps shown in FIG. 2 are formed.

In the etching, part of the silicon oxide film 32 and the silicon nitride film 31 placed on the cap layer 25 may be removed. Furthermore, part of the buffer layer 16 and the interlayer insulating film 14 as the foundation layers of the storage layer 21 may be removed by over-etching for removing the etching residue of the storage layer 21.

Subsequently, as shown in FIG. 3G, the silicon nitride film (third insulating film) 33 whose Si concentration is higher than its stoichiometric mixture ratio is formed sufficiently thick by plasma CVD. Since the Si concentration is higher than the stoichiometric mixture ratio, the silicon nitride film 33 is formed with a sufficient step coverage. Further, since the sidewall of the tunnel barrier layer 22 is covered by the silicon oxide film 32, the silicon nitride film 33 is out of direct contact with the tunnel barrier layer 22.

Subsequently, contact holes are formed after forming the interlayer insulating film 41, and contact plugs 26 are embedded in the contact holes, thereby completing the structure shown in FIG. 1.

Thus, in the embodiment, the silicon nitride films 31 and 33 are formed on the sidewalls of the storage layer 21 and the reference layer 23 of the MTJ element 20, and the silicon oxide film 32 is formed on the sidewall of the tunnel barrier layer 22. Because of this, oxygen as a shortfall can be supplied to MgO of the tunnel barrier layer 22, thereby compensating for insufficiency of oxygen. Moreover, since the sidewall of the tunnel barrier layer 22 is out of contact with the silicon nitride films 31 and 32 of high hydrogen concentration, diffusion of hydrogen from the sidewall insulating film 30 to the tunnel barrier layer 22 can be suppressed. Therefore, the long-term reliability of the tunnel barrier layer 22 can be significantly enhanced.

In addition, since the side surfaces of the storage layer 21 and the reference layer 23 are covered with SiN, oxidization of CoFeB can be suppressed. This enables a highly reliable magnetoresistive memory device to be realized. Although the upper surface of the end portion of the tunnel barrier layer 22 is in contact with the silicon nitride film 31, the area of this portion is extremely small, and hence hydrogen diffusion due to the same counts for nothing. Similarly, although the upper surface of an end of the storage layer 21 is in contact with the silicon oxide film 32, the area of this portion is extremely small, and hence oxidization of the storage layer 21 due to the same also counts for nothing.

Here, it is considered that breakdown of a tunnel barrier layer (MgO) rate-controls the life of an MRAM. As aforementioned, an insulating film, such as a silicon nitride film (SiN), is provided on the sidewall of an MTJ element in order to enhance the reliability of the element. However, in this structure, the reliability of the tunnel barrier layer is degraded by hydrogen emitted from the sidewall insulating film. Also in a NAND flash memory, hydrogen emitted from SiN that protects the tunnel insulating film will significantly degrade the reliability of the tunnel insulating film.

Furthermore, in the MRAM, in order to maintain the characteristics of the MTJ element, this element must be processed at 300° C. or less after magnetic films are formed. However, the side insulating film (SiN film formed by plasma CVD) formed at such a low temperature contains much hydrogen, and hence emits a large amount of hydrogen. The emitted hydrogen will damage the tunnel barrier layer, thereby significantly reducing the long-term reliability.

As described in this embodiment, the long-term reliability of the tunnel barrier layer 22 can be significantly improved by modifying the structure of the sidewall insulating film of the tunnel barrier layer.

### Second Embodiment

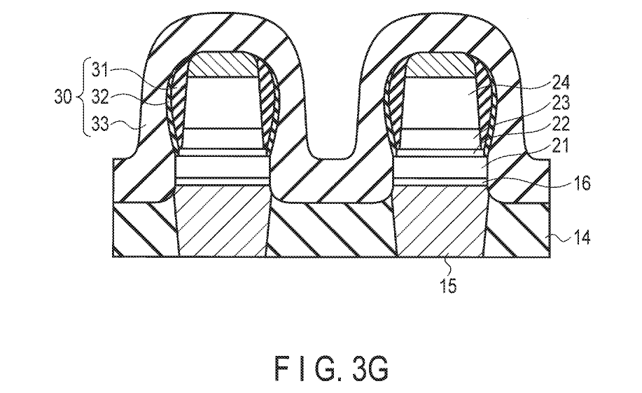

FIG. 4 is a cross-sectional view showing the element structure of a magnetoresistive memory device according to a second embodiment. In this embodiment, elements similar to those of the first embodiment are denoted by corresponding reference numbers, and no detailed description will be given thereof.

In the above-described first embodiment, the silicon oxide film 32 as the second sidewall insulating film is in contact with the sidewall of the tunnel barrier layer 22. However, the silicon oxide film 32 does not necessarily need to be in contact with the sidewall of the tunnel barrier layer 22. If the silicon nitride film 31 touching the end portion of the tunnel barrier layer 22 is sufficiently thin, a reliability improvement effect can be acquired.

Although the second embodiment is similar in fundamental structure to the embodiment shown in FIG. 1, it differs from the latter in that the silicon nitride film 31 as the first sidewall insulating film is in contact with the sidewalls of the tunnel barrier layer 22, the reference layer 23 and the shift adjustment layer 24.

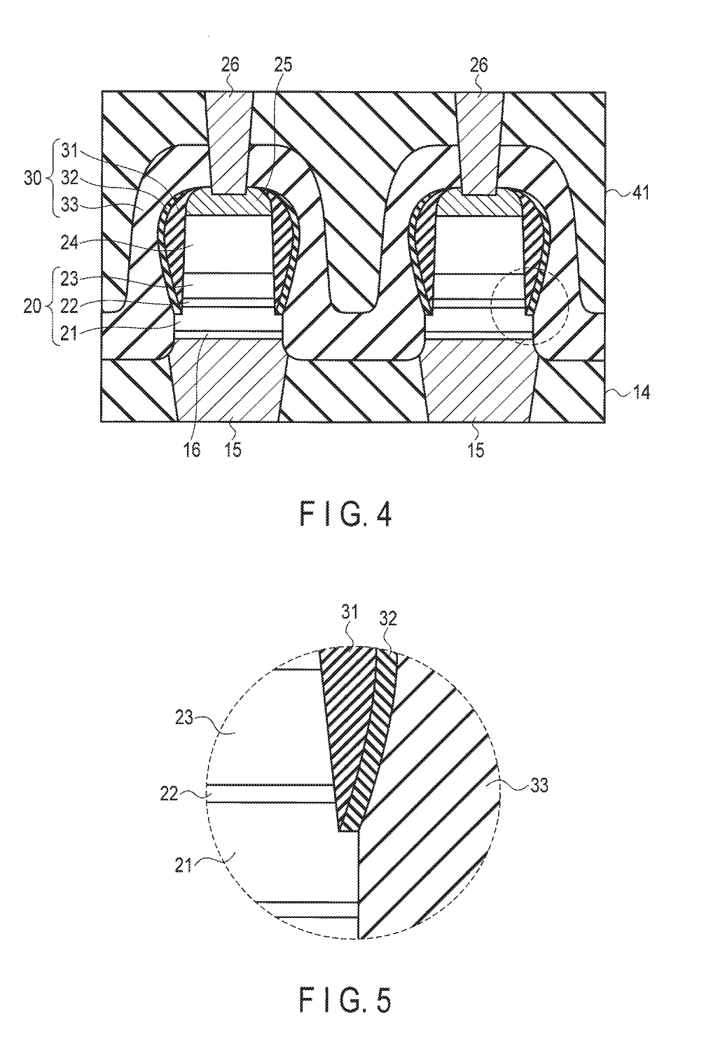

More specifically, as is shown in FIG. 5 that is an enlarged view of the portion marked by the broken line in FIG. 4, the end portion of the storage layer 21 has a step wherein the upper portion of the end portion has the same width as the tunnel barrier layer 22, and the lower portion of the end portion is wider than the upper portion. That is, the storage layer 21 has a terrace formed by removing part of the upper portion of the end portion. Further, the silicon nitride film 31 is also in contact with the sidewall of the upper portion of the storage layer 21. Furthermore, the silicon oxide film 32 is in contact with the terrace of the storage layer 21.

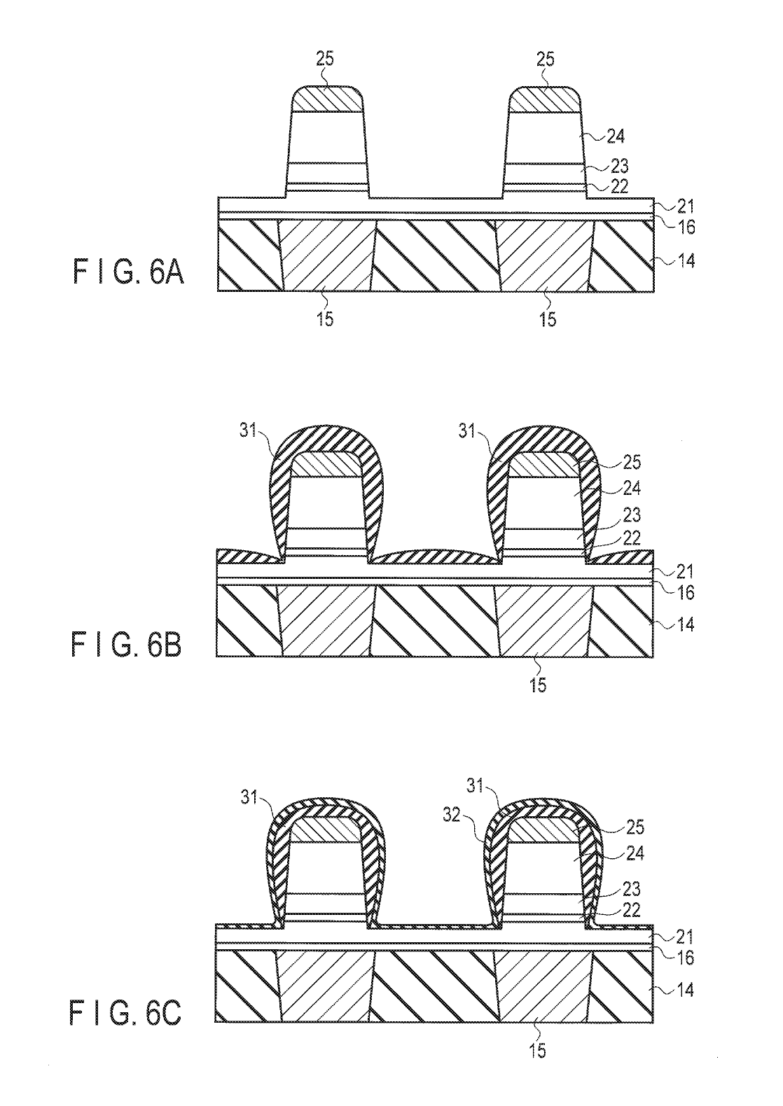

In order to manufacture the magnetoresistive memory device of the second embodiment, in a process corresponding to FIG. 3B, selective etching is performed on the structure by IBE to expose an area ranging from the shift adjustment layer 24 to the storage layer 21, using the cap layer 25 as a mask as shown in FIG. 6A. At this time, the etching may be stopped when the storage layer 21 is exposed, or over-etching may be performed to etch part of the storage layer 21. When over-etching has been performed, a terrace is formed at the upper portion of the storage layer 21.

Subsequently, as shown in FIG. 6B, the silicon nitride film 31 whose nitrogen concentration is higher than its stoichiometric mixture ratio is formed by plasma CVD. The silicon nitride film 31 is formed to cover not only the sidewalls of the cap layer 25, the shift adjustment layer 24 and the reference layer 23, but also the sidewall of the tunnel barrier layer 22 and the sidewall of the upper portion of the storage layer 21.

Since the step coverage of the silicon nitride film 31 is bad, the sidewall portion of the tunnel barrier layer 22 is thinner than the sidewall portion of the reference layer 23. Further, compared to a case where in the process shown in FIG. 6A, the sidewall insulating film is formed after etching is performed to reach the lower surface of the storage layer 21, the silicon nitride film 31 is extremely thin at the sidewall of the tunnel barrier layer 22.

That is, the silicon nitride film 31 on the sidewall of the tunnel barrier layer 22 is thinner than the silicon nitride film 31 on the sidewall of the reference layer 23. The thickness referred to at this time is a thickness seen perpendicularly to the sidewalls of the tunnel barrier layer 22 and the reference layer 23, i.e., a horizontal thickness.

Subsequently, the silicon nitride film 31 on the storage layer 21 is etched by RIE. After that, as shown in FIG. 6C, the silicon oxide film 32 is formed in an ALD process of a low-temperature (300° C. or less).

The silicon oxide film 32 is formed to cover the silicon nitride film 31, and to touch the terrace of the upper portion of the storage layer 21.

After this, selective etching is performed on the storage layer 21, using the silicon oxide film 32 and the cap layer 25 as masks, and then the silicon nitride film 33 whose Si concentration is higher than its stoichiometric mixture ratio is formed by plasma CVD. As a result, the sidewall insulating film 30 having a three-layer structure of SiN/SiO₂/SiN is formed. Further, the interlayer insulating film 41 and the contact plug 26 are formed as in the first embodiment, thereby completing the structure of FIG. 5.

In the second embodiment, although the silicon nitride film 31 as the first sidewall insulating film is in contact with the sidewall of the tunnel barrier layer 22, the contact portion of the silicon nitride film 31 is extremely thin. Because of this, even if the silicon nitride film 31 of a higher hydrogen concentration than the silicon oxide film 32 is in contact with the tunnel barrier layer 22, diffusion of hydrogen from the silicon nitride film 31 to the tunnel barrier layer 22 is extremely small. Therefore, the reliability of the tunnel barrier layer can be enhanced and the same effect as the first embodiment can be acquired.

Moreover, in the second embodiment, since the reference layer 23 and the tunnel barrier layer 22 are simultaneously etched, the number of etching operations can be reduced. In addition, in the second embodiment, it is not necessary to stop etching in a strict manner, which enhances the degree of freedom of treatment.

### Third Embodiment

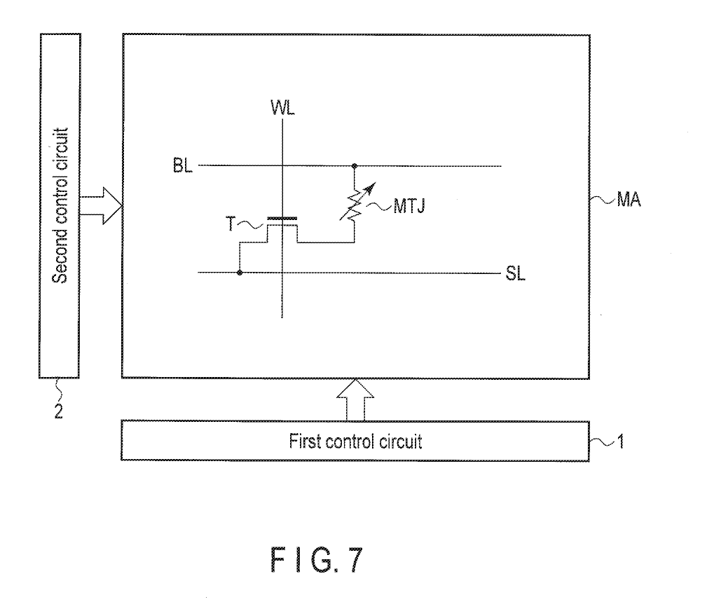

FIG. 7 is a circuit diagram showing the memory cell array of an MRAM according to a third embodiment. The third embodiment employs the magnetoresistive memory device of the above-described first embodiment as each memory cell of the memory cell array.

Each memory cell in a memory cell array MA comprises a series connection of an MTJ element as a magnetoresistive memory element and a switching element (for example, a field-effect transistor [FET]) T. One end of the series connection object (i.e., one end of the MTJ element) is electrically connected to a bit line BL, and the other end of the series connection (one end of the switching element T) is electrically connected to a source line SL.

The control terminal of the switching element T, for example, the gate electrode of an FET, is electrically connected to the word line WL. The potential of the word line WL is controlled by a first control circuit 1. The potential of the bit line BL and source line SL is controlled by a second control circuit 2.

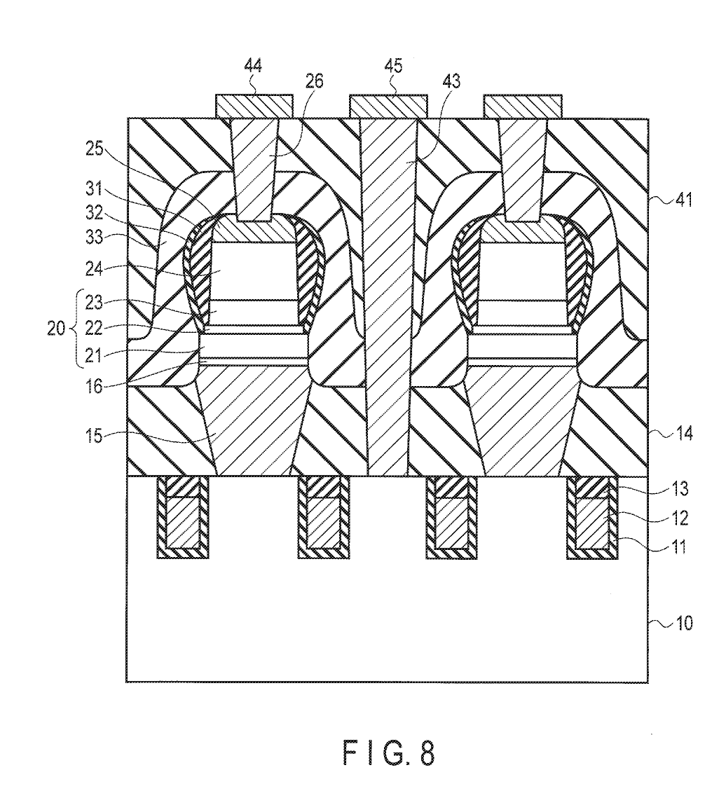

FIG. 8 is a cross-sectional view showing the structure of a memory cell portion of the MRAM shown in FIG. 7. A MOS transistor for switching is formed in the surface of a Si substrate 10, and the interlayer insulating film 14 of, for example, SiO₂, is formed on it. The transistor has an embedded-gate structure wherein a gate electrode 12 is embedded in a groove in the substrate 10 via a gate insulating film 11. The gate electrode 12 is embedded to the middle of the groove, and a protection insulating film 13 formed of, for example, SiN, is formed on it. Moreover, a source/drain area is formed by diffusing a p- or n-type impurity in the substrate 10 on both sides of the embedded-gate structure, although not shown.

The structure of the transistor section is not limited to the embedded-gate structure. For example, a structure in which a gate electrode is formed on the Si substrate via a gate insulating film may be employed instead. It is sufficient if the transistor section functions as a switching element.

A contact hole for connection with the drain of the transistor is formed in the interlayer insulating film 14, and the lower electrode (BEC) 15 is embedded in this contact hole. The lower electrode 15 is formed of, for example, Ta.

To form the above-described structure, the following method, for example, is employed. First, the switching MOS transistor (not shown) having the embedded-gate structure is formed in the surface of the Si substrate, and then the interlayer insulating film 14 formed of, for example, SiO₂, is deposited on the Si substrate 10 by CVD. Subsequently, a contact hole for connection with the drain of the transistor is formed in the interlayer insulating film 14, and then a lower electrode (BEC) 15 formed of Ta crystal is embedded and in the contact hole. More specifically, a Ta film is deposited by sputtering, CVD, etc., on the interlayer insulating film 14 to fill the contact hole. After that, the Ta film is left only in the contact hole by removing the Ta film from the interlayer insulating film by chemical mechanical etching (CMP).

As in the first embodiment, the buffer layer 16, the MTJ element 20, the shift adjustment layer 24 and the cap layer 25 are formed on the lower electrode 15, and the sidewall insulating film 30 is formed to cover the layers 16 to 25. Furthermore, the interlayer insulating film 41 is formed to cover the sidewall insulating film 30, thereby flattening the upper surface of the resultant structure.

Moreover, the contact plug (upper electrode) 26 connected to the cap layer 25 is formed through the interlayer insulating film 41 and the silicon nitride film 33, and a contact plug 43 connected to the source of the transistor section is formed through the interlayer insulating film 41 and the interlayer insulating film 14. Interconnect (BL) 44 connected to contact plug 26 and interconnect (SL) 45 connected to contact plug 43 are formed on the interlayer insulating film 41.

In this structure, silicon nitride films 31 and 33 are formed on the sidewalls of the storage layer 21 and reference layer 23 of the MTJ element 20, and the silicon oxide film 32 is formed on the sidewall of the tunnel barrier layer 22. This structure enables the long-term reliability of the tunnel barrier layer 22 to be enhanced significantly, and oxidization of the storage layer 21 and reference layer 23 to be suppressed. Therefore, the characteristics of the MRAM can be enhanced.

(Modification)

The invention is not limited to the above-described embodiments.

The first and third insulating films as sidewall insulating films are not limited to silicon nitride films. Instead, Al nitride films can be used. Further, the second insulating film as a sidewall insulating film is not limited to a silicon oxide film. Instead, an Al oxide film can be used. Furthermore, regarding the sidewall insulating films, the first and third insulating films are not limited to silicon nitride films, or the second insulating film is not limited to an oxide film. It is sufficient if the amount of hydrogen per unit volume in the second insulating film is less than that in the first or third insulating film.

It is also sufficient if the amount of hydrogen is measured by SIMS for analyzing the mass of secondary ions discharged from the surface of a sample when primary ions, such as Cs⁺ or O₂⁺ ions, are applied thereto. Alternatively, the amount of hydrogen may be measured by RBS for applying ions, such as He⁺ or N⁺ ions, to the surface of a sample to check the way of rebounding of the ions from the sample surface, thereby identifying the size and type of the constituent elements of the sample.

Moreover, each of the first to third insulating films can be appropriately modified in accordance with specifications. If a first insulating film is also formed on the sidewall of a nonmagnetic layer as in the second embodiment, it is sufficient if the first insulating film on the sidewall of the nonmagnetic layer is thinner than the first insulating film on the sidewall of the second magnetic layer.

In this modification, the storage layer of the MTJ element is provided close to the substrate. However, this structure may be modified such that the positions of the storage layer and the reference layer may be reversed. That is, the reference layer may be positioned close to the substrate, and the storage layer may be positioned away from the substrate. If stray magnetic field from the reference layer is small, the shift adjustment layer may be omitted.

The structure of the switching transistor or the lower electrode is not limited to the above-described embodiments or modification, but may be modified appropriately in accordance with the specifications.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistive memory device comprising:
a magnetoresistive element includes a first magnetic layer, a second magnetic layer, and a nonmagnetic layer between the first magnetic layer and the second magnetic layer; and
a sidewall insulating film provided on a sidewall of the magnetoresistive element, and including a first insulating film in contact with a sidewall of the second magnetic layer, a second insulating film in contact with a sidewall of the nonmagnetic layer, and a third insulating film in contact with a sidewall of the first magnetic layer,
wherein a composition of the second insulating film is different from a composition of the first and third insulating film.

2. The device of claim 1, wherein a hydrogen amount of the second insulating film is less than that of each of the first and third insulating films.

3. The device of claim 1, wherein
the first insulating film is a nitride film covering the sidewall of the second magnetic layer;
the second insulating film is an oxide film covering the sidewalls of the nonmagnetic layer and the nitride film; and
the third insulating film is a nitride film covering the sidewall of the first magnetic layer and the oxide film.

4. The device of claim 1, wherein the first and third insulating films are silicon nitride films, and the second insulating film is a silicon oxide film.

5. The device of claim 1, wherein a sidewall of the magnetoresistive element includes a first step of a portion of the first magnetic layer that outwardly protrudes relative to the nonmagnetic layer, and a second step of a portion of the nonmagnetic layer that outwardly protrudes relative to the second magnetic layer.

6. The device of claim 1, wherein the third insulating film is thicker than the first insulating film.

7. The device of claim 1, further comprising a third magnetic layer opposing the second magnetic layer with the nonmagnetic layer interposed therebetween.

8. The device of claim 1, further comprising a semiconductor substrate, a transistor provided for switching in the semiconductor substrate, and a lower electrode connected to the transistor,
wherein the magnetoresistive element is constructed such that the first magnetic layer is provided close to the lower electrode.

9. A magnetoresistive memory device comprising:
a magnetoresistive element includes a first magnetic layer, a second magnetic layer, and a nonmagnetic layer between the first magnetic layer and the second magnetic layer; and
a sidewall insulating film provided on a sidewall of the magnetoresistive element, and including a first insulating film covering a sidewall of the nonmagnetic layer and a sidewall of the second magnetic layer, a second insulating film covering the first insulating film, and a third insulating film covering a sidewall of the first magnetic layer and the second insulating film.

10. The device of claim 9, wherein a hydrogen amount of the second insulating film is less than that of each of the first and third insulating films.

11. The device of claim 9, wherein a portion of the first insulating film placed on the sidewall of the nonmagnetic layer is thinner than a portion of the first insulating film placed on the sidewall of the second magnetic layer.

12. The device of claim 9, wherein the first insulating film is a nitride film, the second insulating film is an oxide film and the third insulating film is a nitride film.

13. The device of claim 9, wherein the first and third insulating films are silicon nitride films, and the second insulating film is a silicon oxide film.

14. The device of claim 9, wherein
an end portion of the first magnetic layer includes a step having an upper side and a lower side outwardly protruding relative to the upper side; and
the first insulating film covers sidewalls of the nonmagnetic layer and the second magnetic layer, and a sidewall of an upper portion of the first magnetic layer.

15. The device of claim 9, further comprising a third magnetic layer opposing the second magnetic layer with the nonmagnetic layer interposed therebetween.

16. The device of claim 9, further comprising a semiconductor substrate, a transistor provided for switching in the semiconductor substrate, and a lower electrode connected to the transistor,
wherein the magnetoresistive element is constructed such that the first magnetic layer is provided close to the lower electrode.

17. A method of manufacturing a magnetoresistive memory device, comprising:
forming, on a substrate, a stacked layer structure comprising a first magnetic layer, a nonmagnetic layer and a second magnetic layer stacked in an order mentioned;
forming, on the stacked layer structure, a mask layer corresponding to a pattern of a magnetoresistive element;
selectively etching the second magnetic layer using the mask layer as a mask;
forming a first sidewall insulating film covering a sidewall of the second magnetic layer exposed by the etching;
selectively etching the nonmagnetic layer using the mask layer and the first sidewall insulating film as masks;
forming a second sidewall insulating film covering a sidewall of the nonmagnetic layer exposed by etching the nonmagnetic layer, and also covering the first sidewall insulating film;
selectively etching the first magnetic layer using the mask layer and the second sidewall insulating film as masks; and
forming a third sidewall insulating film covering a sidewall of the first magnetic layer exposed by etching the first magnetic layer, and also covering the second sidewall insulating film.

18. The method of claim 17, wherein the second sidewall insulating film having a lower hydrogen amount than the first sidewall insulating film and the third sidewall insulating film.

19. The method of claim 18, wherein the first and third insulating films are silicon nitride films, and the second insulating film is a silicon oxide film.

20. The method of claim 18, wherein
the forming the first sidewall insulating film is forming, by plasma CVD, a silicon nitride film having a higher nitrogen content than a stoichiometric mixture ratio thereof;
the forming the second sidewall insulating film is forming a silicon oxide film by an ALD process of 300° C. or less; and
the forming the third sidewall insulating film is forming, by plasma CVD, a silicon nitride film having a higher silicon content than a stoichiometric mixture ratio thereof.
